(19) United States
(12) Patent Application Publication
(10) Pub. No.: US 2020/0125145 A1
(43) Pub. Date: Apr. 23, 2020

(54) CHASSIS MEMBER AND ELECTRONIC APPARATUS

(71) Applicant: LENOVO (SINGAPORE) PTE. LTD., SINGAPORE (SG)

(72) Inventors: Fumitake Mizoguchi, YOKOHAMA (JP); Hiroaki Agata, YOKOHAMA (JP); Tetsuya Ohtani, YOKOHAMA (JP)

(73) Assignee: LENOVO (SINGAPORE) PTE. LTD., SINGAPORE (SG)

(21) Appl. No.: 16/227,782

(22) Filed: Dec. 20, 2018

(30) Foreign Application Priority Data
Oct. 18, 2018 (JP) 2018196454

(51) Int. Cl. G06F 1/16; H05K 5/02

(52) U.S. Cl. CPC G06F 1/1656; G06F 1/1618; G06F 1/1681; H05K 5/02

(57) ABSTRACT

The chassis member includes multiple plate-like fiber-reinforced resin members and a frame part made of material including at least resin. The frame part is bonded to respective outer peripheral end surfaces of the fiber-reinforced resin members and joins the multiple fiber-reinforced resin members together.

### FIELD OF THE INVENTION

The present invention relates to a chassis member and an electronic apparatus including the chassis member.

### BACKGROUND OF THE INVENTION

Chassis of various electronic apparatuses, such as laptop personal computers (PCs), tablet PCs, and smartphones, are required to be lightweight, thin, and high-strength. Accordingly, a plate-like fiber-reinforced resin member including reinforced fiber, such as carbon fiber, impregnated with matrix resin may be used in chassis of an electronic apparatuses (for example, see Japanese Patent No. 5627032).

### SUMMARY OF THE INVENTION

As a method of manufacturing a fiber-reinforced resin member such as the one described above, in general, a method of manufacturing a large fiber-reinforced resin member and cutting this large one into multiple pieces of fiber-reinforced resin members having a product shape is adopted. Therefore, if many fiber-reinforced resin members having the product shape can be cut out from the large one, it is possible to reduce the product cost, and also possible to reduce the amount of useless offcuts.

The present invention has been made in view of the above problem in the conventional technology with the related art, and is intended to provide a chassis member capable of reducing the product cost and an electronic apparatus including the chassis member.

A chassis member according to a first aspect of the present invention includes multiple fiber-reinforced resin members having a plate-like shape and a frame part that is made of material including at least resin, and is bonded to respective outer peripheral end surfaces of the fiber-reinforced resin members and joins the multiple fiber-reinforced resin members together.

According to this configuration, the multiple fiber-reinforced resin members are disposed dispersedly and joined by the frame part. Accordingly, the chassis member can ensure high strength and weight reduction while reducing the amount of fiber-reinforced resin members. Furthermore, it is configured to use the multiple fiber-reinforced resin members; therefore, the fiber-reinforced resin members can be made smaller and efficiently cut out from a large fiber-reinforced resin member, thus the number of products taken out is increased. Accordingly, the fiber-reinforced resin members can reduce the product cost.

The multiple fiber-reinforced resin members may include a first fiber-reinforced resin member and a second fiber-reinforced resin member having a smaller exterior surface area than the first fiber-reinforced resin member. If the fiber-reinforced resin members differ in shape in this way, the efficiency of cutting out fiber-reinforced resin members from a large fiber-reinforced resin member is easily optimized, thus it is possible to further reduce the amount of offcuts and to reduce the product cost.

The chassis member may have a rectangular shape in a planar view. The first fiber-reinforced resin member may be configured to be disposed in a position that includes the center of the chassis member and to extend along a longitudinal direction of the chassis member. The second fiber-reinforced resin member may be configured to be disposed on the side in a longitudinal direction of the first fiber-reinforced resin member and to extend along a lateral direction of the chassis member.

The second fiber-reinforced resin member may include at least one pair of second fiber-reinforced resin members, and the second fiber-reinforced resin members may be configured to be disposed on both sides in the longitudinal direction of the first fiber-reinforced resin member.

The chassis member may have a rectangular shape in a planar view. The first fiber-reinforced resin member may be configured to be disposed in a position that includes the center of the chassis member and to extend along the longitudinal direction of the chassis member. The second fiber-reinforced resin member may be configured to be disposed on the side in a lateral direction of the first fiber-reinforced resin member.

The chassis member may have a rectangular shape in a planar view. Adjacent end surfaces of, of the multiple fiber-reinforced resin members, at least adjacent two fiber-reinforced resin members may be configured to be disposed along a direction intersecting with four sides of the chassis member.

An electronic apparatus according to a second aspect of the present invention includes a chassis that uses the chassis member having any of the configurations described above.

The electronic apparatus may be a clamshell type that includes another chassis openably/closably coupled to the chassis through a hinge, and one surface of the chassis and one surface of the other chassis face each other when the chassis and the other chassis are closed together. The one surface of the other chassis may have an uneven portion. The fiber-reinforced resin member may be configured to be disposed in a position that overlaps with the uneven portion when the chassis and the other chassis are closed together. Accordingly, a load caused by the uneven portion on the chassis can be certainly received by the high-strength fiber-reinforced resin member.

The above-described aspects of the present invention can reduce the product cost.

### BRIEF DESCRIPTION OF THE DRAWINGS

FIG. 1 is a perspective view of an electronic apparatus with a chassis using a chassis member according to an embodiment;

FIG. 2 is a plan view schematically showing a configuration example of a back cover using the chassis member;

FIG. 3 is a cross-sectional view schematically showing a cross-section structure of the chassis member along a line III-III in FIG. 2;

FIG. 4 is a cross-sectional view schematically showing another configuration example of the cross-section structure of the chassis member;

FIG. 5 is a plan view schematically showing the chassis member shown in FIG. 2;

FIG. 6 is a side view of the electronic apparatus shown in FIG. 1 with a lid body closed to an apparatus main body;

FIG. 7 is an explanatory plan view showing an example of a process of cutting out fiber-reinforced resin members from a large original fiber-reinforced resin member;

FIG. 8 is an explanatory plan view showing an example of a process of cutting out fiber-reinforced resin members according to a reference example from the large original fiber-reinforced resin member;

FIG. 9 is a plan view schematically showing a chassis member according to a first modification example;

FIG. 10 is a plan view schematically showing a chassis member according to a second modification example;

FIG. 11 is a plan view schematically showing a chassis member according to a third modification example;

FIG. 12 is a plan view schematically showing a chassis member according to a fourth modification example;

FIG. 13 is a plan view schematically showing a chassis member according to a fifth modification example;

FIG. 14 is a plan view schematically showing a chassis member according to a sixth modification example;

FIG. 15 is a plan view schematically showing a chassis member according to a seventh modification example; and

FIG. 16 is an explanatory plan view showing an example of a process of cutting out fiber-reinforced resin members constituting the chassis member shown in FIG. 15 from the large original fiber-reinforced resin member.

### DETAILED DESCRIPTION OF THE INVENTION

Preferred embodiments of a chassis member according to the present invention and an electronic apparatus using this member will be described in detail below with reference to accompanying drawings.

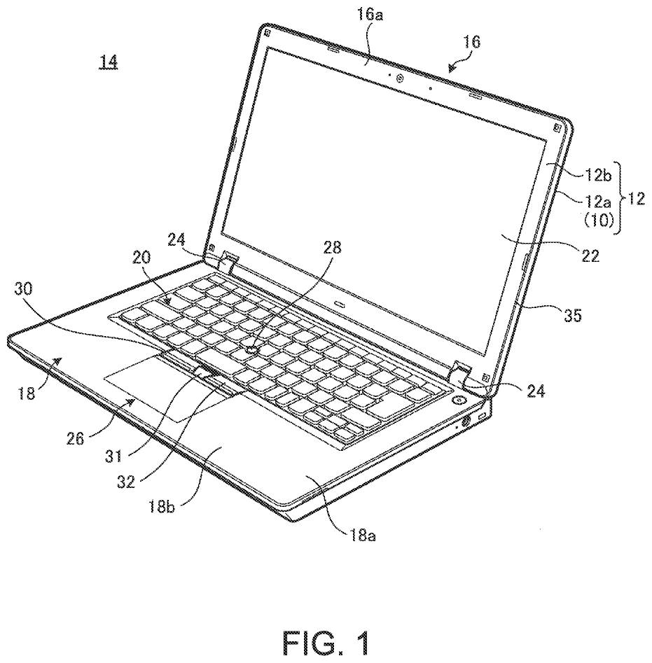

FIG. 1 is a perspective view of an electronic apparatus 14 with a chassis 12 using a chassis member 10 according to an embodiment. In the present embodiment, there is described a configuration example in which the chassis 12 using the chassis member 10 is used as a lid body 16 of the electronic apparatus 14 that is a laptop PC; however, the chassis member 10 may be used in an apparatus main body 18. The chassis member 10 can be used as chassis members of various electronic apparatuses, for example, tablet PCs, desktop PCs, smartphones, etc. as well as laptop PCs.

As shown in FIG. 1, the electronic apparatus 14 includes the apparatus main body 18 with a keyboard device 20 and the lid body 16 with a display device 22 constituted of a liquid crystal display or the like. The electronic apparatus 14 is a clamshell type that the lid body 16 is openably/closably coupled to the apparatus main body 18 by right and left hinges 24.

The apparatus main body 18 is a flat box-like chassis, and houses various electronic components (not shown) such as a circuit board, an arithmetic processing unit, a hard disk drive, and a memory. On a top surface 18a of the apparatus main body 18, the keyboard device 20 and a touchpad device 26 are arranged in a front-to-rear direction. The touchpad device 26 is disposed in a position adjacent to the center front of the keyboard device 20. A pointing stick 28 is provided roughly in the center of the keyboard device 20.

The touchpad device 26 and the pointing stick 28 are for operating a cursor (a mouse pointer) displayed on the display device 22, and are operable input means as substitute for a mouse. The touchpad device 26 is a clickpad that allows a user to perform a touch operation and a press-down operation, for example, by bringing the user's fingertip or the like close to or into contact with the clickpad. Three push buttons 30, 31, and 32 are provided in a position between the keyboard device 20 and the touchpad device 26. The push buttons 30 to 32 work in conjunction with a cursor operation by the touchpad device 26 or the pointing stick 28. The push buttons 30 to 32 are click operation buttons corresponding to the left, center, and right buttons of a general mouse, respectively.

The lid body 16 includes the chassis 12 having a rectangular exterior that a back cover 12a and a front cover 12b are laid over and fastened together. The back cover 12a is a cover member that covers the side and back of the lid body 16. In the present embodiment, the back cover 12a is constituted of the chassis member 10. The front cover 12b is a resin frame-like member that covers the front of the lid body 16, and the display device 22 constituted of, for example, a liquid crystal display is provided in an opening thereof.

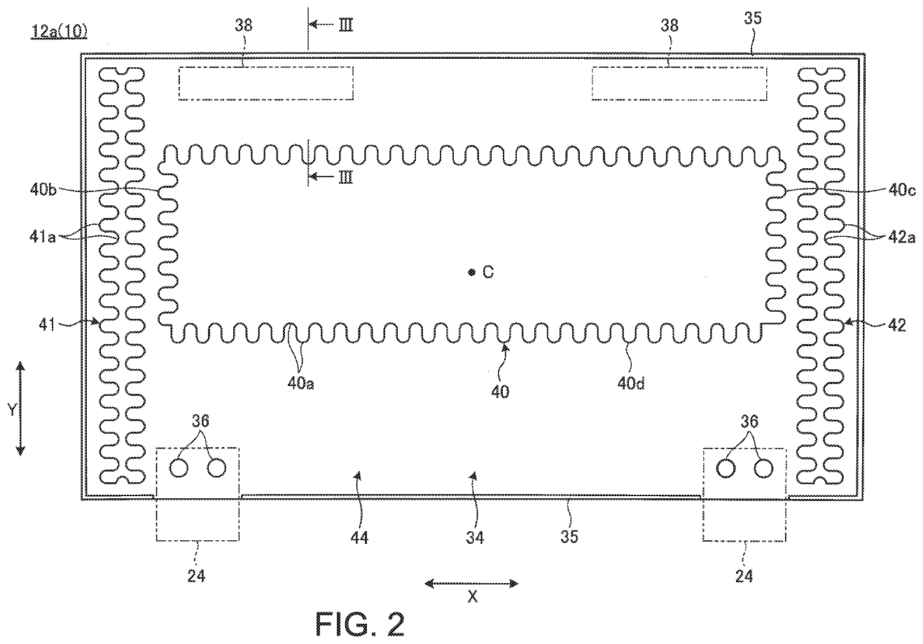

Subsequently, a specific configuration example of the back cover 12a and the chassis member 10 constituting the back cover 12a is described. FIG. 2 is a plan view schematically showing the configuration example of the back cover 12a using the chassis member 10, and illustrates the back cover 12a viewed from the inside.

As shown in FIG. 2, the back cover 12a includes a backboard 34 and a wall part 35 that stands on the periphery of the backboard 34. The backboard 34 constitutes the back of the chassis 12. The wall part 35 constitutes the peripheral side of the chassis 12. The chassis 12 is fastened to the hinges 24 through a pair of right and left attachments 36 each composed of two attachments provided at one edge (a lower edge in FIG. 2) of the backboard 34. At the other edge (an upper edge in FIG. 2) of the backboard 34, a pair of right and left antennas 38 for wireless communication is provided.

The chassis member 10 constituting this back cover 12a includes plate-like fiber-reinforced resin members 40, 41, and 42 and a frame part 44 bonded to respective outer peripheral end surfaces 40a, 41a, and 42a of the fiber-reinforced resin members 40, 41, and 42. The fiber-reinforced resin members 40 to 42 constitute a portion of the backboard 34. The frame part 44 constitutes the other portion of the backboard 34 and the wall part 35.

The fiber-reinforced resin member 40 has the largest exterior surface area (surface area in a planar view) among the three fiber-reinforced resin members 40 to 42. In the configuration example shown in FIG. 2, the fiber-reinforced resin member 40 occupies about one third of the area of the backboard 34 of the chassis member 10. The chassis member 10 in the present embodiment has a rectangular shape in a planar view as shown in FIG. 2. Although the outer peripheral end surface 40a is a corrugated surface, the fiber-reinforced resin member 40 is a rectangular plate member as a whole. The fiber-reinforced resin member 40 extends along a longitudinal direction of the chassis member 10 (a direction of an arrow X in FIG. 2) in a position that includes the center C of the chassis member 10.

The fiber-reinforced resin members 41 and 42 have a smaller exterior surface area than the fiber-reinforced resin member 40. In a case of the present embodiment, the fiber-reinforced resin members 41 and 42 have the same exterior surface area. Although the outer peripheral end surfaces 41a and 42a are a corrugated surface, the fiber-reinforced resin members 41 and 42 are a narrow reed-like plate member as a whole. The fiber-reinforced resin members 41 and 42 are disposed on the both sides (the left and right sides) in a longitudinal direction of the fiber-reinforced resin member 40, respectively, and extend along a lateral direction of the chassis member 10 (a direction of an arrow Y in FIG. 2). That is, the fiber-reinforced resin members 41 and 42 are disposed to face each other on a pair of left and right short sides 40b and 40c of the fiber-reinforced resin member 40, and extend along left and right portions of the wall part 35, respectively.

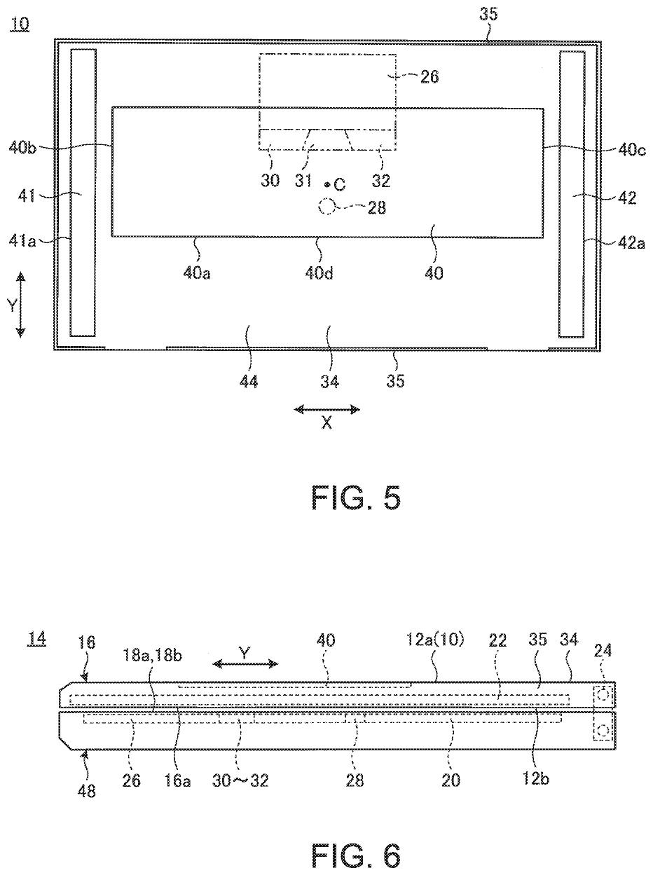

As described above, the outer peripheral end surfaces 40a to 42a of the fiber-reinforced resin members 40 to 42 are configured to be a corrugated surface. This corrugated surface is a structure for enhancing the bonding strength of a resin material bonded to the frame part 44 by injection molding, and its shape can be changed accordingly, or does not have to be provided. It is to be noted that illustrations of these corrugated surfaces are omitted in FIG. 5 and FIGS. 9 to 14 to be described later.

FIG. 3 is a cross-sectional view schematically showing a cross-section structure of the chassis member 10 along a line III-III in FIG. 2. FIG. 3 illustrates, as an example, the fiber-reinforced resin member 40 and a bonded portion and its surroundings of the frame part 44 bonded to the fiber-reinforced resin members 40; however, the other fiber-reinforced resin members 41 and 42 and bonded portions and their surroundings of the frame part 44 bonded to the fiber-reinforced resin members 41 and 42 have the same configuration.

As shown in FIG. 3, the fiber-reinforced resin member (41, 42) is a sandwich-structured laminate that an intermediate layer 48 is provided between a pair of upper and lower fiber-reinforced resin plates 46 and 47. The frame part 44 is bonded to the outer peripheral end surface 40a (41a, 42a) of the fiber-reinforced resin member 40 (41, 42) that is this laminate.

The fiber-reinforced resin plates 46 and 47 are prepreg including reinforced fiber impregnated with matrix resin or a prepreg laminate. In the present embodiment, carbon fiber is used as the reinforced fiber, and, for example, thermoplastic epoxy resin or thermosetting epoxy resin is used as the matrix resin. That is, the fiber-reinforced resin plates 46 and 47 in the present embodiment are carbon fiber reinforced thermo plastics (CFRTP) or CFRP. The reinforced fiber may be fiber other than carbon fiber; for example, metal fiber, such as stainless fiber, and inorganic fiber, such as glass fiber, may be used. A resin material other than thermoplastic epoxy resin or thermosetting epoxy resin may be used as the matrix resin.

The intermediate layer 48 is provided between the pair of fiber-reinforced resin plates 46 and 47, and is a soft spacer that causes these hard fiber-reinforced resin plates 46 and 47 to be separate from each other. The presence of the intermediate layer 48 increases a section modulus of the fiber-reinforced resin member 40 (41, 42) in a through-thickness direction and makes the fiber-reinforced resin member 40 (41, 42) a lightweight and high-strength structure. The intermediate layer 48 is constituted of a foam layer made of, for example, a foam material such as polypropylene, thereby having air-containing voids.

The frame part 44 is bonded to the outer peripheral end surface 40a (41a, 42a) of the fiber-reinforced resin member 40 (41, 42) by injection molding of thermoplastic resin 44a. As the thermoplastic resin 44a that forms the frame part 44, for example, polyethylene resin, polypropylene resin, and the like may be used, or fiber-reinforced resin (for example, GFRP) that reinforced fiber, such as glass fiber, is contained in these resins may be used as well.

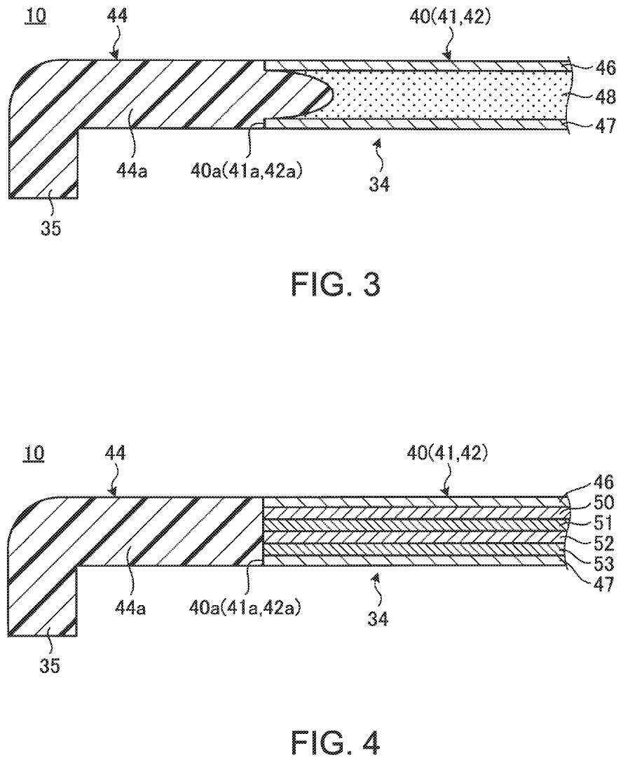

As shown in FIG. 4, the fiber-reinforced resin members 40 to 42 may be constituted of, for example, a plurality of fiber-reinforced resin plates 46, 47, 50, 51, 52, and 53 stacked in layers, without the intermediate layer 48. The fiber-reinforced resin plates 50 to 53 have the same configuration as the fiber-reinforced resin plates 46 and 47.

Thus, the chassis member 10 has a configuration in which the frame part 44 is bonded to the multiple fiber-reinforced resin members 40 to 42. That is, unlike a configuration of the conventional technology in which almost an entire portion that is to be the backboard 34 is covered with one fiber-reinforced resin member, the multiple fiber-reinforced resin members 40 to 42 are disposed dispersedly in a portion of the chassis member 10 that is to be the backboard 34. Accordingly, the chassis member 10 can ensure high strength and weight reduction while reducing the use amount of (the area occupied by) the fiber-reinforced resin members 40 to 42, and can reduce the product cost.

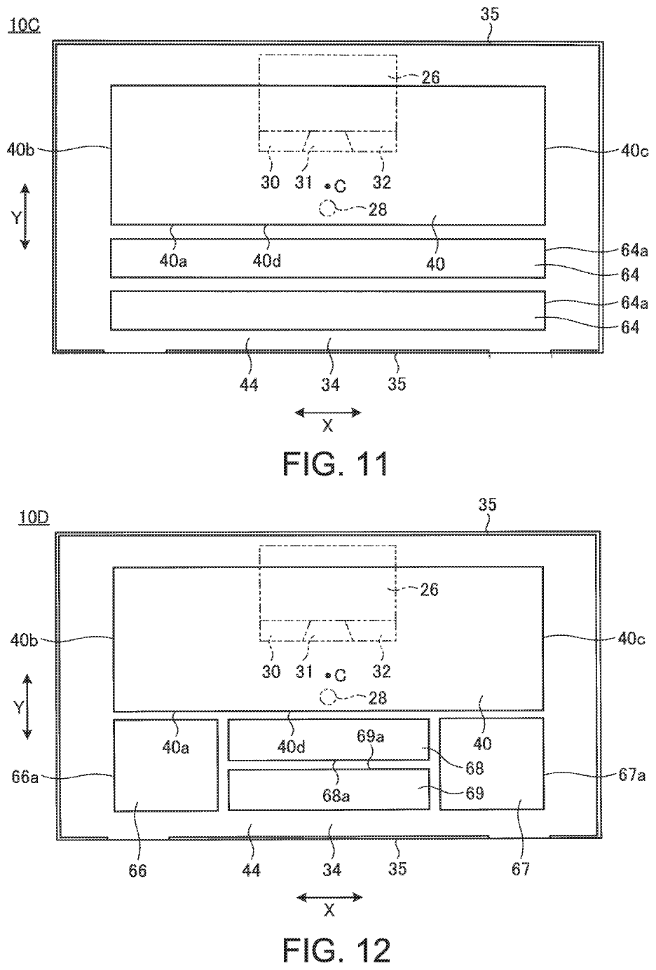

Incidentally, in the electronic apparatus 14, when the lid body 16 is opened and closed, a bending force along the longitudinal direction of the chassis member 10 (an X direction) is applied to the chassis 12 constituting the lid body 16. At this time, in the chassis member 10 constituting the chassis 12, the left and right fiber-reinforced resin members 41 and 42 extend in a direction (a Y direction) perpendicular to the longitudinal direction of the chassis member 10. Furthermore, the dimension of the left and right fiber-reinforced resin members 41 and 42 in the longitudinal direction is longer than the short sides 40b and 40c of the center fiber-reinforced resin member 40. Accordingly, the bending force when the lid body 16 is opened and closed is certainly received by the left and right fiber-reinforced resin members 41 and 42. Therefore, it is possible to certainly prevent the occurrence of stress concentration, for example, on the boundary between a long side 40d of the center fiber-reinforced resin member 40 and the frame part 44, which leads to a crack, etc. on the boundary. Meanwhile, the bending force along the lateral direction of the chassis 12 can be received by the fiber-reinforced resin member 40. It is to be noted that if the bonding strength of a fiber-reinforced resin member and a frame part is sufficiently high, the occurrence of a crack, etc. due to such stress concentration is suppressed; therefore, for example, even in cases of configuration examples shown in FIGS. 10 and 11, it is possible to secure the sufficient practical strength.

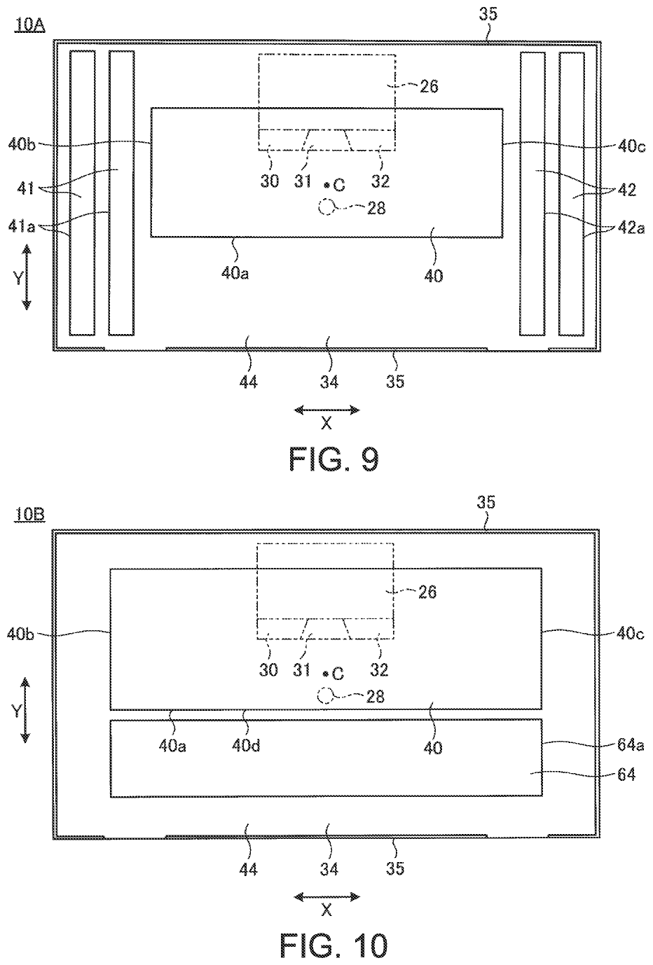

FIG. 5 is a plan view schematically showing the chassis member 10 shown in FIG. 2. FIG. 6 is a side view of the electronic apparatus 14 shown in FIG. 1 with the lid body 16 closed to the apparatus main body 18. In FIG. 5, corrugated surfaces provided on the outer peripheral end surfaces 40a, 41a, and 42a of the fiber-reinforced resin members 40 to 42 are omitted and linearly illustrated; the same applies to FIGS. 9 to 14. The touchpad device 26, the push buttons 30 to 32, and the pointing stick 28 that are indicated by alternate long and two short dashes lines in FIG. 5 indicate their projection positions on the back cover 12a when the lid body 16 closed to the apparatus main body 18, and its front surface 16a on the side of the display device 22 is disposed to face the top surface 18a of the apparatus main body 18; the same applies to FIGS. 9 to 14.

As shown in FIGS. 5 and 6, when the electronic apparatus 14 is in a state where the lid body 16 is closed to the apparatus main body 18, the front surface 16a and the top surface 18a are disposed to face each other. In this state, in the electronic apparatus 14, the fiber-reinforced resin member 40 provided in a portion of the chassis 12 constituting the lid body 16 is disposed in a position that overlaps with a portion of the touchpad device 26, the pointing stick 28, and the push buttons 30 to 32.

In a case of a general laptop PC, a position of the pointing stick 28 in a vertical direction is fixed, and the pointing stick 28 projects upward from the surface of the keyboard device 20 and has a level difference from the surrounding keyboard device 20. The push buttons 30 to 32 are disposed in the opening provided on a frame member 18b (see also FIG. 1) constituting the top surface 18a of the apparatus main body 18, and have a level difference from the surrounding frame member 18b. The touchpad device 26 has a level difference due to the frame member 18b in the boundary with the push buttons 30 to 32 provided on the rear thereof. It is to be noted that even if the electronic apparatus 14 is not provided with the push buttons 30 to 32, there is a level difference due to the frame member 18b in the boundary between the touchpad device 26 and the keyboard device 20 provided on the rear of the touchpad device 26. That is, the top surface 18a of the apparatus main body 18 has an uneven portion due to these level differences.

The chassis 12 of the electronic apparatus 14 includes the fiber-reinforced resin member 40 having higher rigidity than the frame part 44 in a position that overlaps with the uneven portion of the top surface 18a of the apparatus main body 18 when the lid body 16 is closed. Therefore, in the electronic apparatus 14, even in a case where the display device 22 is subjected to a pressing force due to the uneven portion of the apparatus main body 18 when the lid body 16 is closed, its back surface is held by the highly-rigid fiber-reinforced resin member 40. Accordingly, a load caused by the uneven portion of the top surface 18a on the display device 22 can be certainly received by the fiber-reinforced resin member 40, and it is possible to prevent the occurrence of damage or failure of the display device 22.

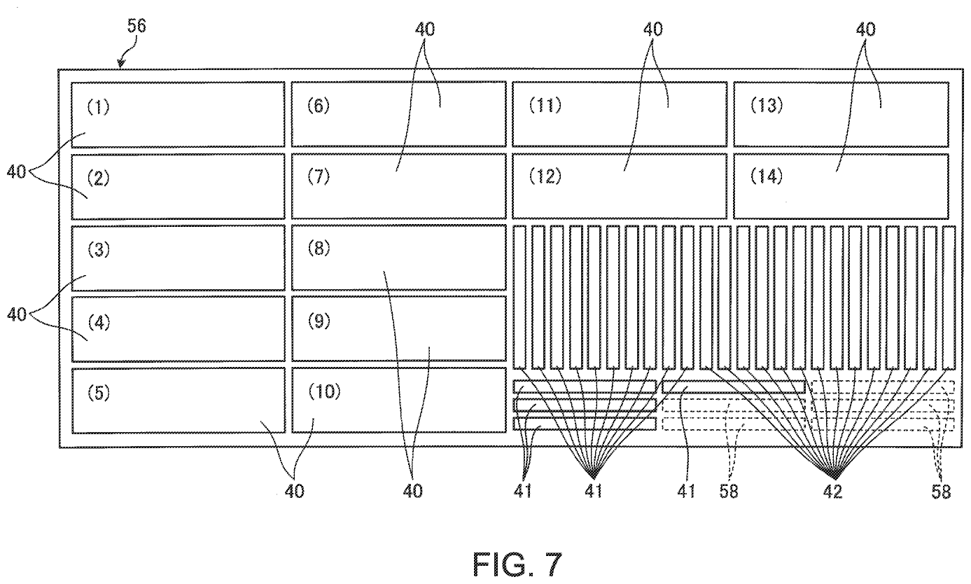

Subsequently, an example of a process of manufacturing the fiber-reinforced resin members 40 to 42 constituting the chassis member 10 is described. FIG. 7 is an explanatory plan view showing an example of a process of cutting out the fiber-reinforced resin members 40 to 42 from a large original fiber-reinforced resin member 56.

As shown in FIG. 7, the fiber-reinforced resin members to 42 in the present embodiment are manufactured by cutting out the fiber-reinforced resin members 40 to 42 from one large original fiber-reinforced resin member 56. The original fiber-reinforced resin member 56 has the same cross-section structure as the fiber-reinforced resin members 40 to 42, and its exterior surface area is large. In a configuration example shown in FIG. 7, fourteen fiber-reinforced resin members 40 with numbers (1) to (14), fourteen fiber-reinforced resin members 41, and fourteen fiber-reinforced resin members 42 are cut out from one original fiber-reinforced resin member 56. It is to be noted that in the configuration example shown in FIG. 7, five fiber-reinforced resin members 58 having the same shape as the fiber-reinforced resin members 41 and 42 can be further cut out from a remnant after the cutting of the fiber-reinforced resin members 40 to 42.

The chassis member 10 in the present embodiment uses the multiple fiber-reinforced resin members 40 to 42 in this way. Accordingly, it is possible to efficiently cut out the multiple fiber-reinforced resin members 40 to 42 from one original fiber-reinforced resin member 56. That is, the number of the fiber-reinforced resin members 40 to 42 constituting the chassis member 10 cut out from one original fiber-reinforced resin member 56 is increased, thus the manufacturing cost of products can be further reduced. Furthermore, by cutting out the fiber-reinforced resin members 58 from the remnant, these fiber-reinforced resin members 58 can be used in combination with fiber-reinforced resin members cut out from another original fiber-reinforced resin member, and therefore the amount of offcuts can be minimized. In the chassis member 10 in the present embodiment, particularly, the fiber-reinforced resin members 41 and 42 have a different shape from the fiber-reinforced resin member 40. Accordingly, as shown in FIG. 7, the efficiency of cutting out the fiber-reinforced resin members from the large fiber-reinforced resin member 56 is easily optimized, thus the amount of offcuts can be further reduced.

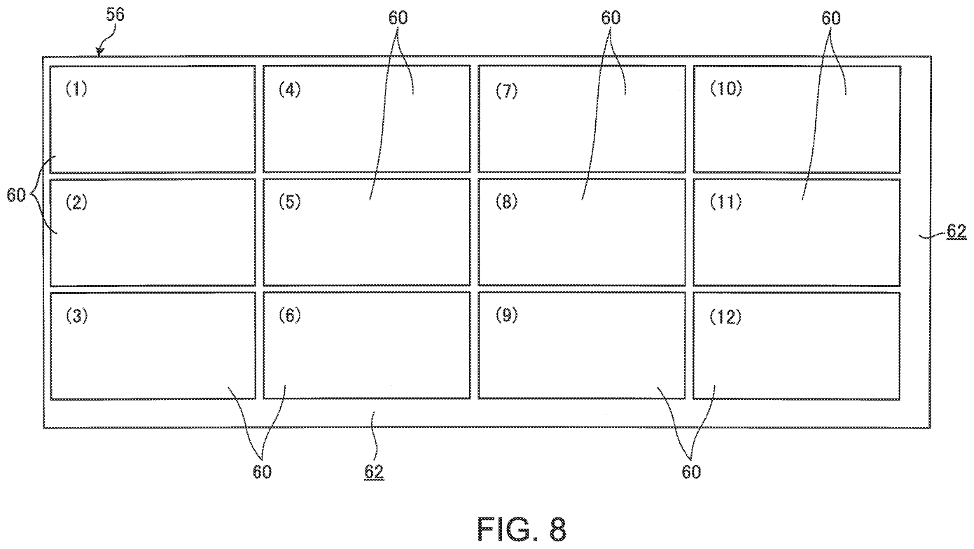

FIG. 8 is an explanatory plan view showing an example of a process of cutting out fiber-reinforced resin members 60 according to a reference example from the large original fiber-reinforced resin member 56. A configuration of the fiber-reinforced resin members 60 according to the reference example is for when one fiber-reinforced resin member 60 is used in one chassis member, just like a configuration of the conventional technology. When one fiber-reinforced resin member 60 is used in one chassis member, the strength of the entire chassis member needs to be secured by one fiber-reinforced resin member 60. Accordingly, the fiber-reinforced resin member 60 needs to have a larger exterior surface area than the fiber-reinforced resin members 40 to 42 in the present embodiment. Therefore, in the reference example shown in FIG. 8, only twelve fiber-reinforced resin members 60 with numbers (1) to (12) can be cut out from one original fiber-reinforced resin member 56, and the number of obtained chassis members is smaller than the case of the present embodiment shown in FIG. 7. Furthermore, a remnant 62 after the cutting has no use, and therefore is dumped as offcuts. Accordingly, a chassis member using the fiber-reinforced resin member 60 according to this reference example substantially increases the manufacturing cost as compared with the case of the present embodiment shown in FIG. 7.

FIG. 9 is a plan view schematically showing a chassis member 10A according to a first modification example. In the chassis member 10A shown in FIG. 9, the dimension of the fiber-reinforced resin member 40 in the longitudinal direction in the chassis member 10 shown in FIG. 5 is modified to be a little smaller, and the respective numbers of the fiber-reinforced resin members 41 and 42 are increased to two. Also in this chassis member 10A, the outer peripheral end surfaces 40a, 41a, and 42a of the fiber-reinforced resin members 40 to 42 are configured to be joined by the frame part 44; therefore, it is possible to reduce the use amount of the fiber-reinforced resin members and to reduce the product cost. Furthermore, the uneven portion due to the pointing stick 28, the push buttons 30 to 32, and the touchpad device 26 is disposed in a position that overlaps with the fiber-reinforced resin member 40; therefore, it is possible to prevent the occurrence of damage or failure of the display device 22 when the lid body 16 is closed.

FIG. 10 is a plan view schematically showing a chassis member 10B according to a second modification example. In the chassis member 10B shown in FIG. 10, a fiber-reinforced resin member 64 is provided instead of the fiber-reinforced resin members 41 and 42 of the chassis member 10 shown in FIG. 5. The fiber-reinforced resin member 64 has a rectangular shape of which the exterior surface area is smaller than the fiber-reinforced resin member 40, and has about the same dimension in the longitudinal direction as the fiber-reinforced resin member 40. The fiber-reinforced resin member 64 is disposed on the side (the front) in the lateral direction of the fiber-reinforced resin member 40, and is arranged parallel to the long side 40d of the fiber-reinforced resin member 40.

FIG. 11 is a plan view schematically showing a chassis member 10C according to a third modification example. In the chassis member 10C shown in FIG. 11, the fiber-reinforced resin member 64 of the chassis member 10B shown in FIG. 10 is modified to be narrower, and the number of the fiber-reinforced resin members 64 is increased to two.

Also in these chassis members 10B and 10C, the outer peripheral end surfaces 40a and 64a of the fiber-reinforced resin members 40 and 64 are configured to be joined by the frame part 44; therefore, it is possible to reduce the use amount of the fiber-reinforced resin members and to reduce the product cost. Furthermore, the uneven portion due to the pointing stick 28, the push buttons 30 to 32, and the touchpad device 26 is disposed in a position that overlaps with the fiber-reinforced resin member 40; therefore, it is possible to prevent the occurrence of damage or failure of the display device 22 when the lid body 16 is closed.

FIG. 12 is a plan view schematically showing a chassis member 10D according to a fourth modification example. In the chassis member 10D shown in FIG. 12, four fiber-reinforced resin members 66, 67, 68, and 69 are provided instead of the fiber-reinforced resin member 64 of the chassis member 10B shown in FIG. 10. The left and right fiber-reinforced resin members 66 and 67 have an approximately square shape of which the exterior surface area is smaller than the fiber-reinforced resin member 40. The fiber-reinforced resin members 66 and 67 are disposed to face each other in left and right ends of the long side 40d of the fiber-reinforced resin member 40. The fiber-reinforced resin members 68 and 69 are provided between the left and right fiber-reinforced resin members 66 and 67, and are arranged in the front-rear direction. The fiber-reinforced resin members 68 and 69 have a shape that the fiber-reinforced resin member 64 shown in FIG. 11 is shortened.

Also in this chassis member 10D, the outer peripheral end surfaces 40a, 67a, 68a, and 69a of the fiber-reinforced resin members 40 and 67 to 69 are configured to be joined by the frame part 44; therefore, it is possible to reduce the use amount of the fiber-reinforced resin members and to reduce the product cost. Furthermore, the uneven portion due to the pointing stick 28, the push buttons 30 to 32, and the touchpad device 26 is disposed in a position that overlaps with the fiber-reinforced resin member 40; therefore, it is possible to prevent the occurrence of damage or failure of the display device 22 when the lid body 16 is closed.

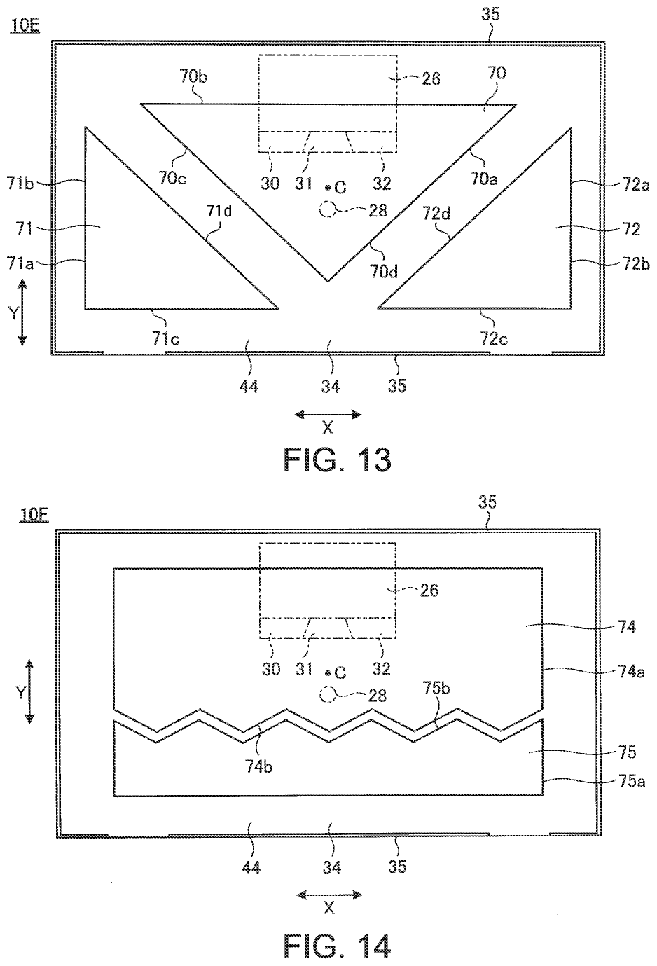

FIG. 13 is a plan view schematically showing a chassis member 10E according to a fifth modification example. In the chassis member 10E shown in FIG. 13, three fiber-reinforced resin members 70, 71, and 72 are provided instead of the fiber-reinforced resin members 40 to 42 of the chassis member 10 shown in FIG. 5. The fiber-reinforced resin member 70 is an isosceles triangle composed of a side 70b along the long side of the chassis member 10E and sides 70c and 70d that intersect with the side 70b. The fiber-reinforced resin members 71 and 72 have a bilaterally symmetrical shape, and are each an isosceles right triangle composed of a side 71b, 72b along the short side of the chassis member 10E, a side 71c, 72c along the long side of the chassis member 10E, and a side 71d, 72d that intersects with the sides 71b, 72b and 71d, 72d. The exterior surface area of the fiber-reinforced resin members 71 and 72 is smaller than that of the center fiber-reinforced resin member 70.

Also in this chassis member 10E, outer peripheral end surfaces 70a, 71a, and 72a of the fiber-reinforced resin members 70 to 72 are configured to be joined by the frame part 44; therefore, it is possible to reduce the use amount of the fiber-reinforced resin members and to reduce the product cost. Furthermore, the uneven portion due to the pointing stick 28, the push buttons 30 to 32, and the touchpad device 26 is disposed in a position that overlaps with the fiber-reinforced resin member 70; therefore, it is possible to prevent the occurrence of damage or failure of the display device 22 when the lid body 16 is closed. Moreover, in the chassis member 10E, the sides 70a and 70c of the fiber-reinforced resin member 70, the side 71d of the fiber-reinforced resin member 71, and the side 72d of the fiber-reinforced resin member 72 extend in directions that intersect with the four sides of the chassis member 10E. That is, in the chassis member 10E, the fiber-reinforced resin members 70 to 72 are arranged with the long side of the chassis member 10E so as to form a V-shaped gap. Accordingly, in the chassis member 10E, the bending force when the lid body 16 is opened and closed can be certainly received by the fiber-reinforced resin members 70 to 72, and the strength of products is improved further.

FIG. 14 is a plan view schematically showing a chassis member 10F according to a sixth modification example. In the chassis member 10F shown in FIG. 14, fiber-reinforced resin members 74 and 75 are provided instead of the fiber-reinforced resin members 40 and 64 of the chassis member 10B shown in FIG. 10. Of an outer peripheral end surface 74a of the fiber-reinforced resin member 74, an end surface 74b adjacent to the fiber-reinforced resin member 75 has a zigzag shape. Likewise, an outer peripheral end surface 75a of the fiber-reinforced resin member 75, an end surface 75b adjacent to the end surface 74b of the fiber-reinforced resin member 74 has a zigzag shape. These zigzag end surfaces 74b and 75b are disposed to face each other like meshing gears so that the protruding portion of one of the end surfaces are fit into the recessed portion of the other end surface.

Also in this chassis member 10F, outer peripheral end surfaces 74a and 75a of the fiber-reinforced resin members 74 and 75 are configured to be joined by the frame part 44; therefore, it is possible to reduce the use amount of the fiber-reinforced resin members and to reduce the product cost. Furthermore, the uneven portion due to the pointing stick 28, the push buttons 30 to 32, and the touchpad device 26 is disposed in a position that overlaps with the fiber-reinforced resin member 74; therefore, it is possible to prevent the occurrence of damage or failure of the display device 22 when the lid body 16 is closed. Moreover, in the chassis member 10F, by disposing the fiber-reinforced resin members 74 and 75 so that their zigzag end surfaces 74b and 75b fit together, the fiber-reinforced resin members 74 and 75 are arranged so as to form a zigzag-shaped gap extended in a longitudinal direction of the chassis member 10F. Accordingly, in the chassis member 10F, the bending force when the lid body 16 is opened and closed can be certainly received by the fiber-reinforced resin members 74 and 75, and the strength of products is improved further.

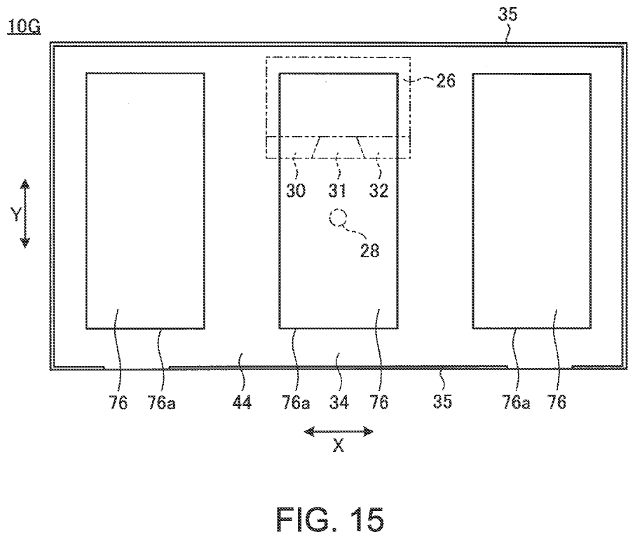

FIG. 15 is a plan view schematically showing a chassis member 10G according to a seventh modification example. FIG. is an explanatory plan view showing an example of a process of cutting out fiber-reinforced resin members constituting the chassis member 10G shown in FIG. 15 from a large original fiber-reinforced resin member. In the above-described configuration examples, the chassis member 10 or the like configured to use the fiber-reinforced resin members 40 to 42 or the like having different shapes are described as an example; however, the chassis member may be constituted of a plurality of fiber-reinforced resin members having the same shape. The chassis member 10G shown in FIG. 15 is constituted of three fiber-reinforced resin members 76 having the same shape. The fiber-reinforced resin members 76 are disposed side by side at regular intervals along the long side (in a direction of an arrow X) of the chassis member 10G, and extend along the short side (in a direction of an arrow Y) of the chassis member 10G.

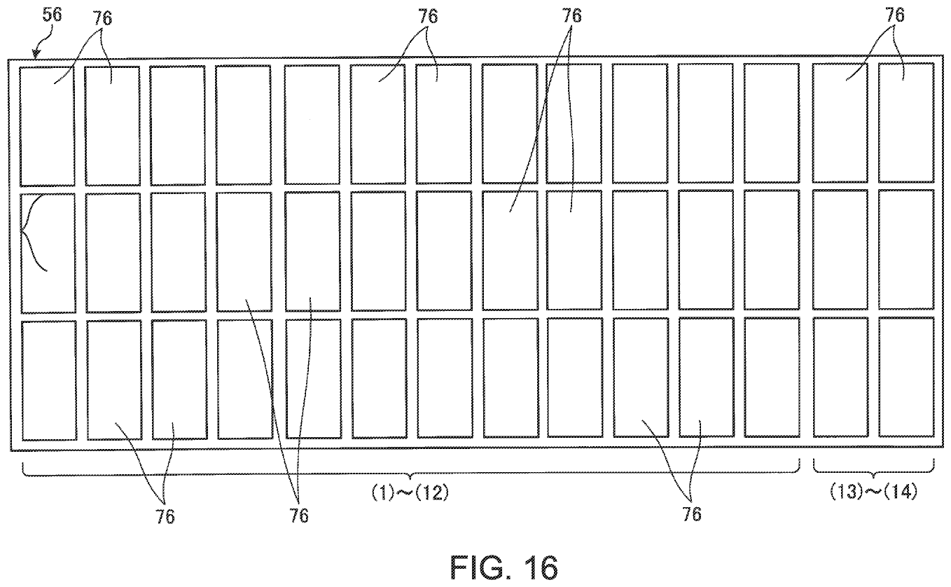

As shown in FIG. 16, for example, 42 fiber-reinforced resin members 76 constituting the chassis member 10G can be cut out from one large original fiber-reinforced resin member 56. That is, in a configuration example shown in FIG. 16, 14 sets of the three fiber-reinforced resin members 76 with numbers (1) to (14) can be obtained from one original fiber-reinforced resin member 56. Therefore, as compared with the fiber-reinforced resin members 60 according to the reference example shown in FIG. 8, two sets more of the fiber-reinforced resin members 76 can be cut out from one original fiber-reinforced resin member 56, and the number of the fiber-reinforced resin members 76 taken out is increased.

Also in this chassis member 10G, respective outer peripheral end surfaces 76a of the fiber-reinforced resin members 76 are configured to be joined by the frame part 44; therefore, it is possible to reduce the use amount of the fiber-reinforced resin members and to reduce the product cost. Furthermore, most of the uneven portion due to the pointing stick 28, the push buttons 30 to 32, and the touchpad device 26 is disposed in a position that overlaps with the center fiber-reinforced resin member 76; therefore, it is possible to prevent the occurrence of damage or failure of the display device 22 when the lid body 16 is closed. Moreover, in the chassis member 10G, fiber-reinforced resin members 76 having an exterior surface area that is large to some extent are disposed on the right and left sides of the chassis member 10G. Accordingly, also in the chassis member 10G, the bending force when the lid body 16 is opened and closed can be certainly received by the fiber-reinforced resin members 76, and the strength of products is improved further.

As described above, even in a case where fiber-reinforced resin members constituting a chassis member have the same shape, while the number of the fiber-reinforced resin members taken out is increased by reducing the occupancy rate of the fiber-reinforced resin members in the chassis member, the fiber-reinforced resin member can be certainly disposed in a position that requires the strength. Meanwhile, in a case where you attempt to increase the number of fiber-reinforced resin members taken out while a chassis member is constituted of one fiber-reinforced resin member, it may be difficult to certainly dispose the fiber-reinforced resin member in a position that requires the strength, and it may cause a problem in the strength of products.

It is to be noted that the present invention is not limited to the above-described embodiment; needless to say, modifications can be freely made without departing from the scope of the invention.

1. A chassis member comprising:
multiple fiber-reinforced resin members having a plate-like shape; and
a frame part that is made of material including at least resin, and that is bonded to respective outer peripheral end surfaces of the fiber-reinforced resin members and that joins the multiple fiber-reinforced resin members together.

2. The chassis member according to claim 1, wherein the multiple fiber-reinforced resin members include a first fiber-reinforced resin member and a second fiber-reinforced resin member having a smaller exterior surface area than an exterior surface area of the first fiber-reinforced resin member.

3. The chassis member according to claim 2, wherein:
the chassis member has a rectangular shape in a planar view,
the first fiber-reinforced resin member is disposed in a position that includes a center of the chassis member, and extends along a longitudinal direction of the chassis member, and
the second fiber-reinforced resin member is disposed on a side, in a longitudinal direction, of the first fiber-reinforced resin member, and extends along a lateral direction of the chassis member.

4. The chassis member according to claim 3, wherein the second fiber-reinforced resin member includes at least one pair of second fiber-reinforced resin members, and the second fiber-reinforced resin members are disposed on both sides in the longitudinal direction of the first fiber-reinforced resin member.

5. The chassis member according to claim 2, wherein:
the chassis member has a rectangular shape in a planar view,
the first fiber-reinforced resin member is disposed in a position that includes a center of the chassis member, and extends along a longitudinal direction of the chassis member, and
the second fiber-reinforced resin member is disposed on a side, in a lateral direction, of the first fiber-reinforced resin member.

6. The chassis member according to claim 1, wherein:
the chassis member has a rectangular shape in a planar view, and
adjacent end surfaces of at least adjacent two fiber-reinforced resin members are disposed along a direction intersecting with four sides of the chassis member.

7. An electronic apparatus comprising:
a chassis having a chassis member that includes:
multiple fiber-reinforced resin members having a plate-like shape; and
a frame part that is made of material including at least resin, and that is bonded to respective outer peripheral end surfaces of the fiber-reinforced resin members and that joins the multiple fiber-reinforced resin members together.

8. The electronic apparatus according to claim 7, wherein:
the electronic apparatus is a clamshell type that includes another chassis openably/closably coupled to the chassis through a hinge, and one surface of the chassis and one surface of the other chassis face each other when the chassis and the other chassis are closed together,
the one surface of the other chassis has an uneven portion, and
one of the fiber-reinforced resin member is disposed in a position that overlaps with the uneven portion when the chassis and the other chassis are closed together.
